(19) United States
(12) Patent Application Publication
(10) Pub. No.: US 2009/0320902 A1
(43) Pub. Date: Dec. 31, 2009

(54) SOLAR ENERGY COLLECTING DEVICE

(75) Inventors: CHI-CHUNG HU, Chu-Nan (TW); YAO-MIN TSENG, Chu-Nan (TW); CHIH-MING LAI, Chu-Nan (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXSEMICON INTEGRATED TECHNOLOGY, INC., Chu-Nan (TW)

(21) Appl. No.: 12/347,283

(22) Filed: Dec. 31, 2008

(30) Foreign Application Priority Data
Jun. 25, 2008 (CN) 200810302308.6

(51) Int. Cl. H01L 31/052

(52) U.S. Cl. 136/246

(57) ABSTRACT

A solar energy collecting device includes a photovoltaic module, a light reflecting unit, and a support unit. The photovoltaic module is configured to convert solar energy to electrical energy, and includes a front portion and a rear portion opposite to the front portion. The light reflecting unit is positioned below the photovoltaic module and has a concave curved surface opposite to the rear portion. The support unit supports the photovoltaic module.

### BACKGROUND

1. Technical Field

The disclosure relates to a solar energy collecting device.

2. Description of Related Art

Currently, various solar energy collecting devices have been designed to receive and convert solar energy into electrical energy. Such solar energy collecting devices have been applied on roofs of buildings, cars, illuminating devices, and on various portable electronic devices.

A typical energy collecting device includes a photovoltaic panel and a supporter. The photovoltaic panel is fixed on the supporter and has a light incident portion. When solar lights are perpendicularly irradiated on the light incident portion, the typical energy collecting device has the highest efficiency. However, when the solar lights are not perpendicularly irradiated on the light incident portion, the efficiency of the typical energy collecting device decreases significantly. As a result, the typical energy collecting device does not have a reliable efficiency.

Therefore, a new solar energy collecting device is desired to overcome the above-described shortcoming.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a perspective view of a first embodiment of a solar energy collection device.

FIGS. 2 to 4 are cross-sectional views of the solar energy collection device of FIG. 1.

FIG. 5 is a cross-sectional view of a second embodiment of a solar energy collection device.

FIG. 6 is a cross-sectional view of a third embodiment of a solar energy collection device.

FIG. 7 is a cross-sectional view of a fourth embodiment of a solar energy collection device.

FIG. 8 is a cross-sectional view of a fifth embodiment of a solar energy collection device.

FIG. 9 is a perspective view of a sixth embodiment of a solar energy collection device.

### DETAILED DESCRIPTION OF THE EMBODIMENTS

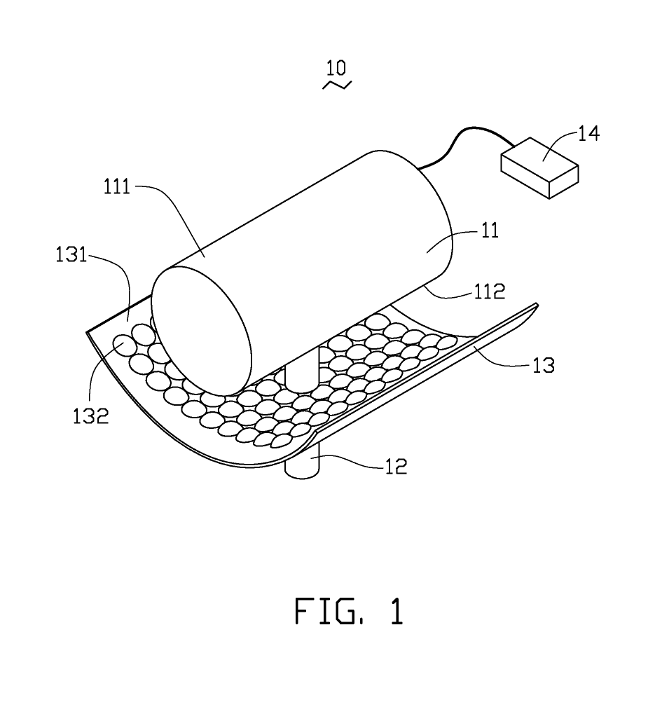

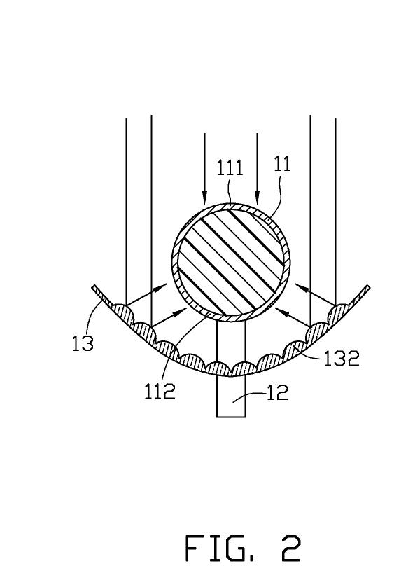

Referring to FIGS. 1 and 2, a first embodiment of a solar energy collecting device 10 includes a photovoltaic module 11, a support unit 12, a light reflecting unit 13 and an energy storage unit 14.

The photovoltaic module 11 is configured to convert solar energy to electrical energy, and has a front portion 111 and a rear portion 112 opposite to the front portion 111. The front portion 111 is configured to face solar light. The photovoltaic module 11 is flexible and may contain semiconductor materials such as silicon, and semiconductor materials of group III-V compounds (e.g. AlAs, InAs, InP, GaP, GaAs, GaN) and group II-VI compounds (e.g. CIGS/CIS, CdTe). The photovoltaic module 11 may be cylindrical-shaped or prism-shaped. In the illustrated embodiment, the photovoltaic module 11 is cylindrical shaped.

The light reflecting unit 13 has a concave curved surface 131. A plurality of light reflecting micro-members 132 is positioned on the concave curved surface 131 and arranged in a matrix arrangement. Each light reflecting member 132 may be a spherical-shaped protrusion, a spherical-shaped recess, or a pyramid-shaped recess. In the illustrated embodiment, each light reflecting member 132 is a spherical-shaped protrusion.

The support unit 12 supports the photovoltaic module 11 and the light reflecting unit 13. In one embodiment, the support unit 12 is rod-shaped.

In assembly, the support unit 12 passes through the light reflecting unit 13 and supports the photovoltaic module 11. The light reflecting unit 13 is positioned below the photovoltaic module 11 and secured on the support unit 12. The concave curved surface 131 is opposite to the rear portion 112. The energy storage unit 14 is electrically coupled to the photovoltaic module 11 and configured to store electrical energy converted by the photovoltaic module 11. In one embodiment, the photovoltaic module 11 is coated with organic dye materials to form electrodes electrically coupled to the energy storage unit 14.

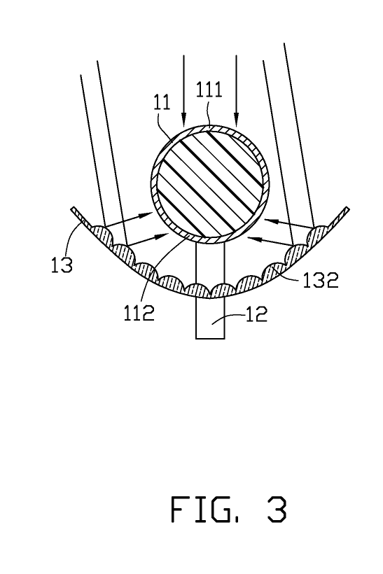

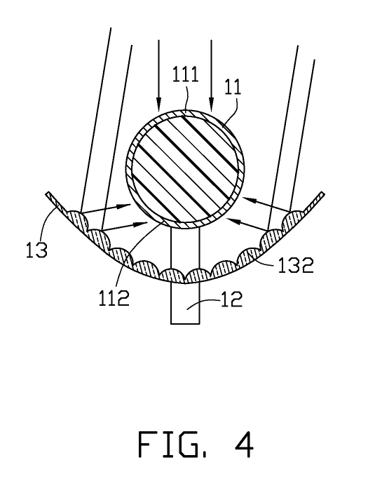

Also referring to FIGS. 3 and 4, in use, a portion of solar lights are transmitted to the front portion 111 and absorbed by the front portion 111. The remainder of the solar lights is transmitted to the concave curved surface 131 and the light reflecting members 132, and is reflected to the rear portion 112 by the concave curved surface 131 and the light reflecting members 132. The rear portion 112 absorbs the remainder of the solar lights and converts solar energy to electrical energy.

The front and rear portions 111. 112 can effectively absorb the solar lights, even if solar light is not directly irradiated on the front portion 111, because of the concave curved surface 131, and the light reflecting members 132. Therefore, the solar energy collecting device 10 has a reliable efficiency.

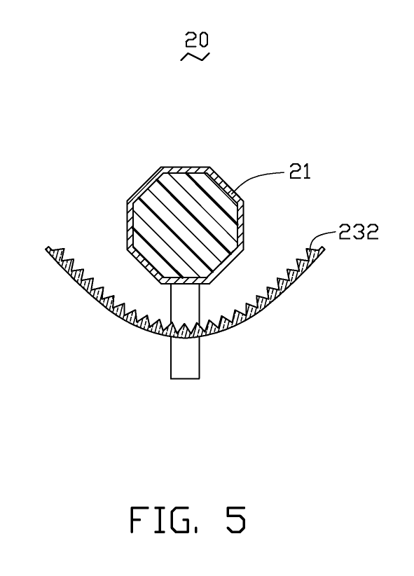

Referring to FIG. 5, a second embodiment of a solar energy collecting device 20 is similar to the first embodiment of the solar energy collecting device 10, except that the photovoltaic module 21 may be polyhedron-shaped or spherical-shaped. Each light reflecting micro-member 232 is a pyramid-shaped protrusion. In this embodiment, the photovoltaic module 21 is polyhedron-shaped.

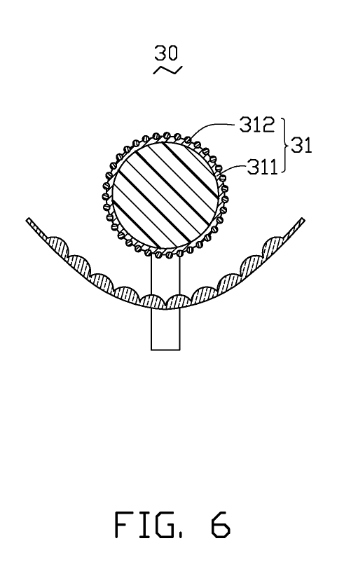

Referring to FIG. 6, a third embodiment of a solar energy collecting device 30 is similar to the first embodiment of the solar energy collecting device 10, except that the photovoltaic module 31 includes a flexible substrate 311 and a plurality of spherical photovoltaic units 312. The spherical photovoltaic units 312 are positioned on the substrate 311 and may be made of silicon.

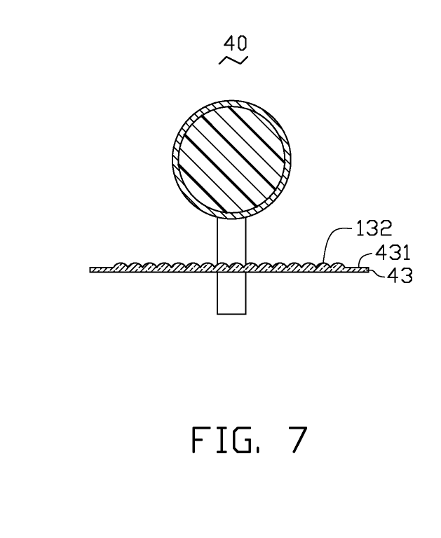

Referring to FIG. 7, a fourth embodiment of a solar energy collecting device 40 is similar to the first embodiment of the solar energy collecting device 10, except that the light reflecting unit 43 has a planar surface 431, and the light reflecting micro-members 132 are positioned on the planar surface 431.

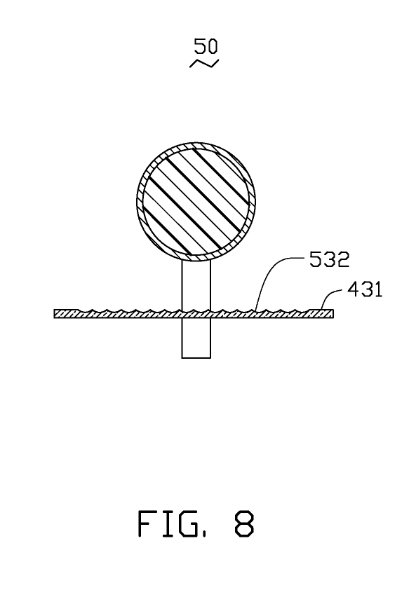

Referring to FIG. 8, a fifth embodiment of a solar energy collecting device 50 is similar to the fourth embodiment of the solar energy collecting device 40, except that each light reflecting micro-member 532 is a spherical-shaped or a pyramid-shaped recess defined in the planar surface 431.

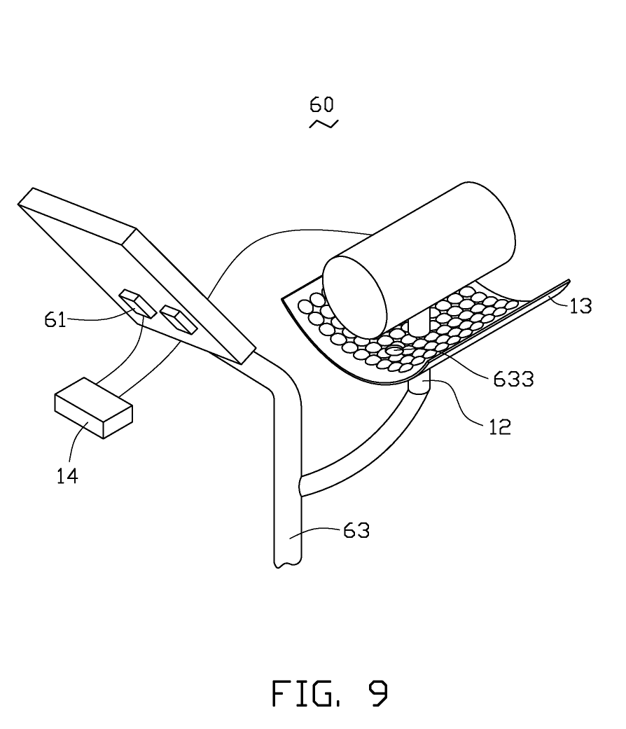

Referring to FIG. 9, a sixth embodiment of a solar energy collecting device 60 is similar to the first embodiment of the solar energy collecting device 10, except that the solar energy collecting device 60 further includes a light emitting module 61 and a support component 63. The light emitting module 61 is electrically coupled to the energy storage unit 14 and supported by the support component 63. In one embodiment, the light emitting module 61 includes a plurality of light emitting diodes. The support unit 12 is connected to the support component 63. A plurality of through holes 633 is defined in the light reflecting unit 13 and configured to allow liquid, such as water to pass through.

It is believed that the present embodiments and their advantages will be understood from the foregoing description, and it will be apparent that various changes may be made thereto without departing from the spirit and scope of the embodiments or sacrificing all of its material advantage.

What is claimed is:

1. A solar energy collecting device, comprising:
a photovoltaic module configured to convert solar energy to electrical energy, and having a front portion and a rear portion opposite to the front portion;
a light reflecting unit positioned below the photovoltaic module and having a concave curved surface opposite to the rear portion; and
a support unit supporting the photovoltaic module.

2. The solar energy collecting device of claim 1, further comprising an energy storage unit electrically coupled to the photovoltaic module.

3. The solar energy collecting device of claim 1, wherein the photovoltaic module is cylindrical-shaped, prism-shaped, spherical-shaped, or polyhedron-shaped.

4. The solar energy collecting device of claim 1, wherein the photovoltaic module comprises a substrate and a plurality of spherical photovoltaic units positioned on the substrate.

5. The solar energy collecting device of claim 4, wherein the plurality of spherical photovoltaic units are made of silicon.

6. The solar energy collecting device of claim 1, further comprising a plurality of light reflecting micro-members positioned on the concave curved surface.

7. The solar energy collecting device of claim 6, wherein the plurality of light reflecting micro-members is arranged in a matrix arrangement.

8. The solar energy collecting device of claim 6, wherein each light reflecting micro-member is a spherical-shaped protrusion, a pyramid-shaped protrusion, a spherical-shaped recess, or a pyramid-shaped recess.

9. The solar energy collecting device of claim 2, further comprising a light emitting module electrically coupled to the energy storage unit, and a support component supporting the light emitting module and connected to the support unit.

10. The solar energy collecting device of claim 1, wherein a plurality of through holes is defined in the light reflecting unit.

11. The solar energy collecting device of claim 1, wherein the support unit passes through the light reflecting unit; the light reflecting unit is secured on the support unit.

12. A solar energy collecting device, comprising:
a photovoltaic module configured to convert solar energy to electrical energy, and comprising a front portion and a rear portion opposite to the front portion;
a light reflecting unit positioned below the photovoltaic module and having a planar surface opposite to the rear portion;
a plurality of light reflecting micro-members positioned on the planar surface; and
a support unit supporting the photovoltaic module.

13. The solar energy collecting device of claim 12, further comprising an energy storage unit electrically coupled to the photovoltaic module.

14. The solar energy collecting device of claim 12, wherein the photovoltaic module is cylindrical-shaped, prism-shaped, spherical-shaped, or polyhedron-shaped.

15. The solar energy collecting device of claim 12, wherein the photovoltaic module comprises a substrate and a plurality of spherical photovoltaic units positioned on the substrate.

16. The solar energy collecting device of claim 15, wherein the plurality of spherical photovoltaic units are made of silicon.

17. The solar energy collecting device of claim 12, wherein the plurality of light reflecting micro-members is arranged in a matrix arrangement.

18. The solar energy collecting device of claim 12, wherein each light reflecting micro-member is a spherical-shaped protrusion, a pyramid-shaped protrusion, a spherical-shaped recess, or a pyramid-shaped recess.

19. The solar energy collecting device of claim 13, further comprising a light emitting module electrically coupled to the energy storage unit, and a support component supporting the light emitting module and connected to the support unit.

20. The solar energy collecting device of claim 12, wherein the support unit passes through the light reflecting unit; the light reflecting unit is secured on the support unit.
